(19) United States
(12) Patent Application Publication
(10) Pub. No.: US 2026/0198033 A1
(43) Pub. Date: Jul. 9, 2026

(54) SEMICONDUCTOR DEVICE AND METHODS FOR FORMING THE SAME

(71) Applicant: Taiwan Semiconductor Manufacturing Company Limited, Hsinchu (TW)

(72) Inventors: Hsin-Yu Lai, Hsinchu (TW); Kuo-Chang Chiang, Hsinchu (TW); Chih-Yu Chang, New Taipei City (TW); Katherine H. Chiang, New Taipei City (TW)

(21) Appl. No.: 19/186,812

(22) Filed: Apr. 23, 2025

Related U.S. Application Data
(60) Provisional application No. 63/743,431, filed on Jan. 9, 2025.

(51) Int. Cl. H10D 30/01; H01L 21/426; H10D 30/67; H10D 62/80; H10D 86/01; H10D 86/40

(52) U.S. Cl. CPC H10D 30/0316; H10D 30/6732; H10D 30/6758; H10D 86/0212; H10D 86/411; H10P 30/22; H10D 62/875

(57) ABSTRACT

A method of forming a semiconductor device includes forming a gate electrode, a source electrode, and a drain electrode within a first dielectric material layer, forming a gate dielectric layer over the first dielectric material layer, forming source and drain contact via structures through the gate dielectric layer on the source and drain electrodes, and forming an active layer over the gate dielectric layer. End portions of the active layer may be converted into a source region and a drain region by implanting electrical dopants. A semiconductor structure includes a gate electrode, source and drain electrodes within a first dielectric material layer, a gate dielectric layer overlying the first dielectric material layer, source and drain contact via structures vertically extending through the gate dielectric layer and contacting the source and drain electrodes, and an active layer overlying the gate dielectric layer.

### CROSS-REFERENCE TO RELATED APPLICATIONS

This application claims the benefit of priority from U.S. Provisional Application Ser. No. 63/743,432 filed on Jan. 9, 2025 and entitled “Channel-last BEOL TFT device,” the entire contents of which are incorporated herein by reference for all purposes.

### BACKGROUND

Thin-film transistors (TFTs) offer several advantages, including low power consumption, high switching speed, and compatibility with flexible substrates. However, the manufacture of high-performance TFTs faces multiple challenges. One such challenge is achieving high carrier mobility while maintaining low off-state current. Additionally, integrating TFTs into back-end-of-line (BEOL) processes presents complications due to thermal budget constraints and potential damage to underlying layers during fabrication. Furthermore, TFTs may exhibit inconsistent performance and reliability issues stemming from variations in doping levels and electrical characteristics. The fabrication process may introduce defects and damage to the metal oxide semiconductor channels, particularly during etching and deposition steps. Thus, TFTs with reduced defects and enhanced performance characteristics are desired.

### BRIEF DESCRIPTION OF DRAWINGS

Aspects of the present disclosure are best understood from the following detailed description when read with the accompanying figures. The various features of elements may not be drawn to scale, and some elements may be omitted in the drawings for clarity.

FIG. 1A is a vertical cross-sectional view of an exemplary structure after formation of connection metal via structures according to an embodiment of the present disclosure. FIG. 1B is a top-down view of the exemplary structure of FIG. 1A. The vertical plane A-A′ is the cut plane of the vertical cross-sectional view of FIG. 1A.

FIG. 2A is a vertical cross-sectional view of the exemplary structure after formation of source electrode, drain electrode, and gate electrodes according to an embodiment of the present disclosure. FIG. 2B is a top-down view of the exemplary structure of FIG. 2A. The vertical plane A-A′ is the cut plane of the vertical cross-sectional view of FIG. 2A.

FIG. 3 is a vertical cross-sectional view of the exemplary structure after formation of a gate dielectric layer and a hard mask layer according to an embodiment of the present disclosure.

FIG. 4A is a vertical cross-sectional view of the exemplary structure after formation of openings through the hard mask layer and the gate dielectric layer according to an embodiment of the present disclosure. FIG. 4B is a top-down view of the exemplary structure of FIG. 4A. The vertical plane A-A′ is the cut plane of the vertical cross-sectional view of FIG. 4A.

FIG. 5 is a vertical cross-sectional view of the exemplary structure after deposition of a metallic material layer according to an embodiment of the present disclosure.

FIG. 6A is a vertical cross-sectional view of the exemplary structure after formation of source contact via structures and drain contact via structures according to an embodiment of the present disclosure. FIG. 6B is a top-down view of the exemplary structure of FIG. 6A. The vertical plane A-A′ is the cut plane of the vertical cross-sectional view of FIG. 6A.

FIG. 7 is a vertical cross-sectional view of the exemplary structure after deposition of a semiconducting metal oxide material layer and an ion implantation mask material layer according to an embodiment of the present disclosure.

FIG. 8A is a vertical cross-sectional view of the exemplary structure after patterning of the ion implantation mask layer and the semiconducting metal oxide material layer into stacks of a respective ion implantation mask layer and an active layer according to an embodiment of the present disclosure. FIG. 8B is a top-down view of the exemplary structure of FIG. 8A. The vertical plane A-A′ is the cut plane of the vertical cross-sectional view of FIG. 8A.

FIG. 9A is a vertical cross-sectional view of the exemplary structure after forming of implantation mask openings through the ion implantation mask layers according to an embodiment of the present disclosure. FIG. 9B is a top-down view of the exemplary structure of FIG. 9A. The vertical plane A-A′ is the cut plane of the vertical cross-sectional view of FIG. 9A.

FIG. 10A is a vertical cross-sectional view of the exemplary structure after performing an ion implantation process that forms source regions and drain regions according to an embodiment of the present disclosure. FIG. 10B is a top-down view of the exemplary structure of FIG. 10A. The vertical plane A-A′ is the cut plane of the vertical cross-sectional view of FIG. 10A.

FIG. 11 is a vertical cross-sectional view of the exemplary structure after formation of a second dielectric material layer according to an embodiment of the present disclosure.

FIG. 12 is a vertical cross-sectional view of a first alternative configuration of the exemplary structure according to embodiments of the present disclosure.

FIG. 13 is a vertical cross-sectional view of a second alternative configuration of the exemplary structure according to embodiments of the present disclosure.

FIG. 14 is a vertical cross-sectional view of a third alternative configuration of the exemplary structure according to embodiments of the present disclosure.

FIG. 15 is a first flow chart illustrating a first sequence of processing steps for forming a semiconductor structure according to an embodiment of the present disclosure.

FIG. 16 is a first flow chart illustrating a second sequence of processing steps for forming a semiconductor structure according to an embodiment of the present disclosure.

### DETAILED DESCRIPTION

The following disclosure provides many different embodiments, or examples, for implementing various features of the provided subject matter. Specific examples of components and arrangements are described below to clarify the present disclosure. These are merely examples, and are not limiting. Drawings are not drawn to scale. Elements with the same reference numerals refer to the same element, and are presumed to have the same material composition and the same thickness range unless expressly indicated otherwise. All features of an original embodiment are presumed to be present in any derived embodiment unless expressly disclosed otherwise. Thus, features described with reference to related embodiments in the drawings and/or in the specification provide support for features in an embodiment. Embodiments are expressly contemplated in which multiple instances of any described element are repeated unless expressly stated otherwise. Embodiments are expressly contemplated in which non-essential elements are omitted even if such embodiments are not expressly disclosed but are known in the art.

Further, spatially relative terms, such as “beneath,” “below,” “lower,” “above,” “upper” and the like, may be used herein for ease of description to describe geometrical features among elements as illustrated in the figures. A first physical element is “embedded” with a second physical element if the entire volume of the first element is located within a hypothetical volume defined by a set of hypothetical surfaces having the least total surface area among all sets of hypothetical surfaces containing the entirety of the outer surfaces of the second element and topologically homeomorphic to a spherical surface. Such a set of hypothetical surfaces covers each opening, if present, in the outer surfaces with a minimum-area surface segment among all possible opening-free surface segments. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

As used herein, removal of a first material is “selective to” a second material if the removal rate of the first material is greater than the removal rate of the second material at least by a factor of 3. Unless otherwise expressly indicated, removal of the first material selectively to the second material implies the possibility of the ratio of the removal rates equal to, or greater than, 3.0, and/or 10, and/or 100, and/or 1,000. As used herein, a first surface and a second surface are “vertically coincident” with each other if the second surface overlies or underlies the first surface, and if the first surface and the second surface may be entirely contained within a common vertical plane, which may be straight or contoured in a horizontal cross-sectional view.

Embodiments of the present disclosure may provide semiconductor structures with enhanced performance characteristics and reduced defects. In some aspects, the semiconductor structures may include a gate electrode, a source electrode, and a drain electrode positioned within a first dielectric material layer. A gate dielectric layer may be formed over the first dielectric material layer. A source contact via structure is formed through the gate dielectric layer to contact the source electrode, and a drain contact via structure is formed through the gate dielectric layer and to contact the drain electrode. An active layer may be formed overlying the gate dielectric layer.

A source region and a drain region may be formed by implanting electrical dopants into end portions of the active layer. For this purpose, an ion implantation mask plate may be formed over the active layer. The ion implantation mask plate comprises a pair of implantation mask openings through which the electrical dopants may be implanted. This configuration may allow for precise control over the doping process while minimizing damage to other portions of the active layer, particularly the channel region. The channel-last approach used in forming these structures may reduce exposure of the active layer to potentially damaging processes, thereby minimizing defects in the semiconducting metal oxide material. The source region may be formed directly on a top surface of an underlying source contact via structure, and the drain region may be formed directly on a top surface of an underlying drain contact via structure. Thus, all electrodes of a thin film transistor may be contacted from below (i.e., bottom contact) without the need formation of any overlying contact structure.

The various embodiments thin film transistors disclosed herein may achieve high carrier mobility while maintaining low off-state current. In some embodiments, a second dielectric material layer may be formed on sidewalls of the implantation mask openings, top surface segments of the source and drain regions, and the top surface of the ion implantation mask plate. Such an embodiment configuration may provide electrical isolation between adjacent thin film transistors and act as a protective or passivation layer. Various embodiment structures disclosed herein may be suitable for integration into back-end-of-line (BEOL) processes with reduced complications related to thermal budget constraints and potential damage to underlying layers.

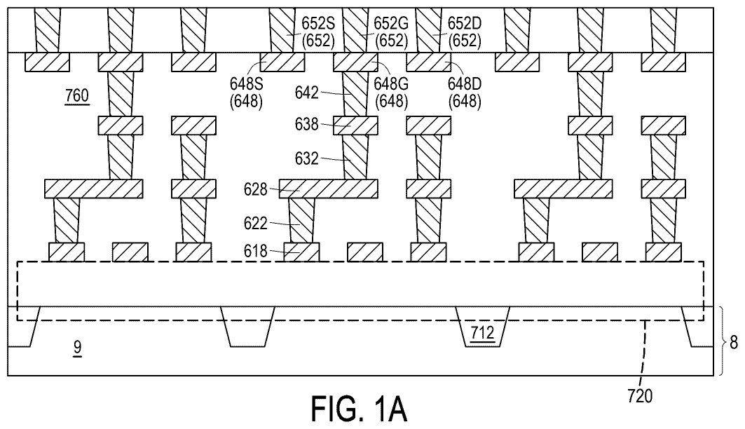

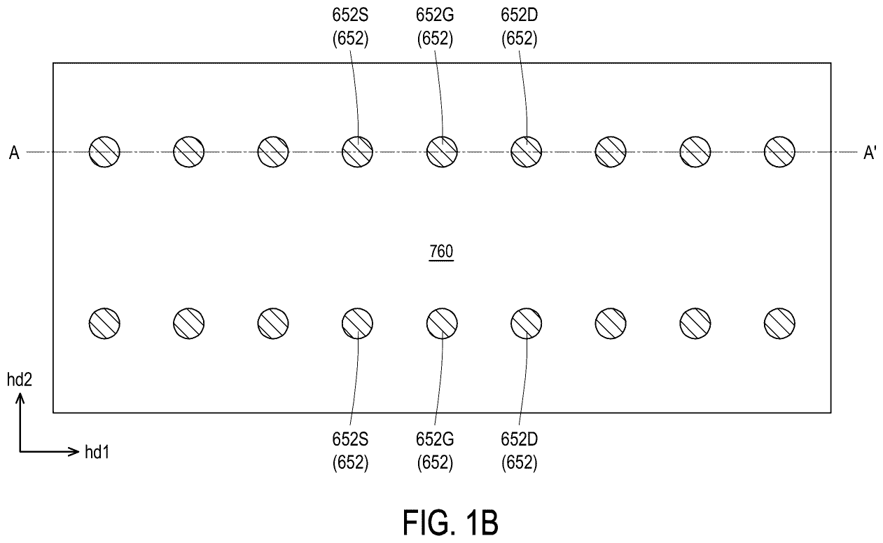

Referring to FIGS. 1A and 1B, an exemplary structure is provided, which is a semiconductor structure containing a substrate 8 that includes a semiconductor material layer 9. For example, the substrate 8 may comprise a semiconductor substrate such as a commercially available silicon wafer. Shallow trench isolation structures 712 may be formed within a surface portion of the semiconductor material layer 9. Semiconductor devices may be formed within box 720. The details of the semiconductor device 720 are omitted to simplify the drawings. Semiconductor devices 720 may be integrated within the structure at a lower level, positioned above the shallow trench isolation structures 712. The semiconductor devices 720 may include a variety of components and configurations. In some aspects, the semiconductor devices 720 may comprise field effect transistors including a respective portion of the semiconductor material layer 9 as a semiconductor channel. In some embodiments, the semiconductor devices 720 may form a complementary metal-oxide-semiconductor (CM OS) circuit.

Interconnect structures may be formed above the semiconductor devices 720. The interconnect structures may include metal interconnect structures embedded within dielectric material layers, which are herein referred to as lower-level metal interconnect structures (618, 622, 628, 632, 638, 642, 648, 652). As used herein, “lower levels” refer to metal interconnect levels that underlie the thin film transistors to be subsequently formed. In contrast, “upper levels” refer to metal interconnect levels that overlie the thin film transistors to be subsequently formed. Structures that are formed in the lower levels are herein referred to as lower-level structures. Structures that are formed in the upper levels are herein referred to as upper-level structures.

Generally, the lower-level metal interconnect structures (618, 622, 628, 632, 638, 642, 648, 652) comprise multiple levels of metal lines (618, 628, 638, 648) and metal via structures (622, 632, 642, 652) that are interconnected to one another to provide electrically conductive paths to and from various electrical nodes of the semiconductor devices 720. Contact-level metal interconnect structures (not illustrated) may be formed at the level of the semiconductor devices 720, and the first-interconnect-level metal lines 618 may be formed on the contact-level metal interconnect structures. Second-interconnect-level metal via structures 622, second-interconnect-level metal lines 628, third-interconnect-level metal via structures 632, third-interconnect-level metal lines 638, fourth-interconnect-level metal via structures 642, and fourth-interconnect-level metal lines 648 may be sequentially formed from bottom to top.

In the exemplary structure, the fourth-interconnect-level metal lines 648 formed within one of the lower-level dielectric material layers 760 may include metal lines configured to provide electrical connections to various electrical nodes of thin film transistors to be subsequently formed. For example, the fourth-interconnect-level metal lines 648 may include source-connection metal lines 648S, gate-connection metal lines 648G, and drain-connection metal lines 648D. Subsequently, fifth-interconnect-level metal via structures 652 formed within another of the lower-level dielectric material layers 760 may be formed. The fifth-interconnect-level metal via structures 652 may include source-connection metal via structures 652S, gate-connection metal via structures 652G, and drain-connection metal via structures 652D. In one embodiment, top surfaces of the source-connection metal via structures 652S, the gate-connection metal via structures 652G, and the drain-connection metal via structures 652D may be formed within a horizontal plane including a topmost surface of the lower-level dielectric material layers 760. Put another way, the top surfaces of the source-connection metal via structures 652S, the gate-connection metal via structures 652G, the drain-connection metal via structures 652D and the topmost surface of the lower-level dielectric material layers 760 may all be co-planar with one another.

In one embodiment, the channel direction (i.e., the current flow direction) of the thin film transistors may be along a first horizontal direction hd1. In this embodiment, each set of a source-connection metal via structure 652S, a gate-connection metal via structure 652G, and a drain-connection metal via structure 652D to be connected to a thin film transistor to be subsequently formed may be arranged along the first horizontal direction hd1. In some embodiments, a rectangular array of thin film transistors may be subsequently formed, which may have the first horizontal direction hd1 as a first direction of periodicity and having a second horizontal direction hd2 as a second direction of periodicity. In this embodiment, the set of a source-connection metal via structure 652S, a gate-connection metal via structure 652G, and a drain-connection metal via structure 652D may be repeated as a two-dimensional periodic array.

While the present disclosure is described using an embodiment in which the source-connection metal lines 648S, the gate-connection metal lines 648G, and the drain-connection metal lines 648D are formed at the fourth line level, and the source-connection metal via structures 652S, the gate-connection metal via structures 652G, and the drain-connection metal via structures 652D are formed in a fifth via level, the source-connection metal lines 648S, the gate-connection metal lines 648G, and the drain-connection metal lines 648D, the source-connection metal via structures 652S, the gate-connection metal via structures 652G, and the drain-connection metal via structures 652D may be formed at a lower metal interconnect levels or at upper metal interconnect levels. Such alternative embodiments are expressly within the contemplated scope of disclosure.

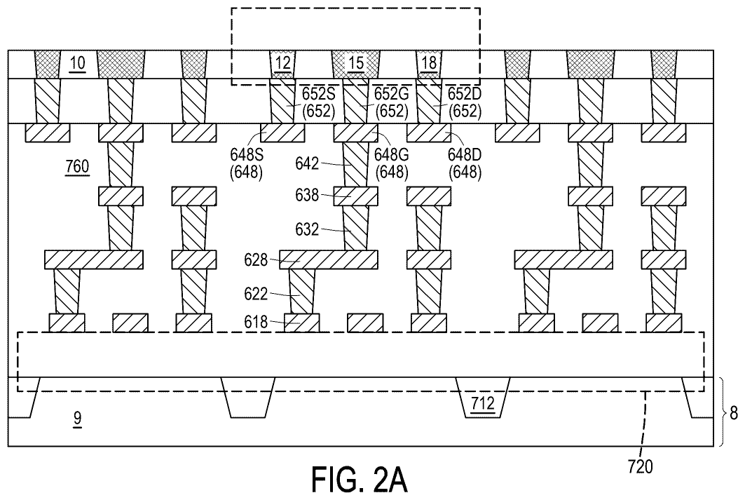

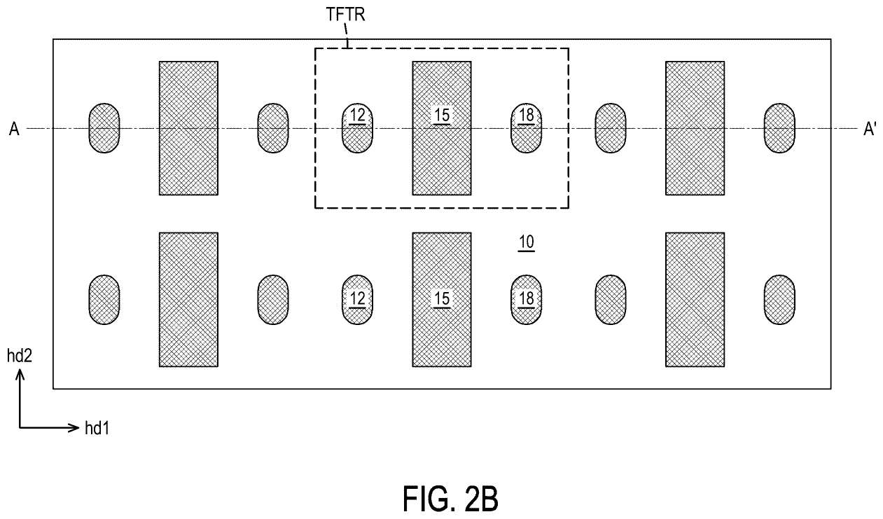

Referring to FIGS. 2A and 2B, a first dielectric material layer 10 may be formed over the lower-level dielectric material layers 760 and metal interconnect structures embedded therein. The first dielectric material layer 10 may comprise silicon oxide, silicon nitride, or silicon oxynitride. A source electrode 12, a gate electrode 15, and a drain electrode 18 may be formed within the first dielectric material layer 10. The source electrode 12, the gate electrode 15, and the drain electrode 18 may comprise a metal or a metal silicide.

Each volume within which a thin film transistor is to be subsequently formed is herein referred to as a thin film transistor region TFTR. In one embodiment, the source electrode 12, the gate electrode 15, and the drain electrode 18 within each thin film transistor region TFTR may be arranged along the first horizontal direction hd1. The source electrode 12 and the drain electrode 18 may have an oval shape or a circular shape in a plan view (such as the view of FIG. 2B), while the gate electrode 15 may have a rectangular shape in the plan view. The gate electrode 15 within each thin film transistor region TFTR may have a pair of sidewalls that are parallel to the second horizontal direction hd2 and having a greater lateral extent than the lateral extent of an active layer to be subsequently formed in the thin film transistor region TFTR. The areas of the source electrode 12 and the drain electrode 18 in each thin film transistor region TFTR may be located entirely within the area of the active region to be subsequently formed within the thin film transistor region TFTR.

The source electrode 12, the gate electrode 15, and the drain electrode 18 within each thin film transistor region TFTR may be electrically connected to the underlying interconnect structure. For example, the source electrode 12 within each thin film transistor region TFTR may be connected to, and may directly contact, the top surface of, an underlying source-connection metal via structure 652S. The drain electrode 18 within each thin film transistor region TFTR may be connected to, and may directly contact, the top surface of, an underlying drain-connection metal via structure 652D. The gate electrode 15 within each thin film transistor region TFTR may be connected to, and may directly contact, an underlying gate-connection metal via structures 652G. Generally, the bottom surface of each source electrode 12 does not coincide with the top surface of the respective underlying source-connection metal via structure 652S. Put another way, the horizontal cross sectional shape of the source electrode may not exactly match the horizontal cross sectional shape of the underlying source-connection metal via structure 652S. The bottom surface of each drain electrode 18 does not coincide with the top surface of the respective underlying drain-connection metal via structure 652D. The periphery of the bottom surface of each source electrode 12 may be rectangular or substantially rectangular, and may be laterally offset outward from the periphery of the top surface of the respective underlying gate-connection metal via structure 652G.

In one embodiment, the source electrodes 12, the gate electrodes 15, and the drain electrodes 18 may be formed by patterning via-shaped cavities and pad-shaped trenches in the first dielectric material layer 10, by depositing at least one metallic material (such as a combination of a metallic barrier liner and a metallic fill material) in the via-shaped cavities and the pad-shaped cavities, and by removing excess portions of the at least one metallic material from above the horizontal plane including the top surface of the first dielectric material layer 10 by performing a planarization process, which may comprise a chemical mechanical polishing (CM P) process and/or a selective recess etch process that remove(s) the at least one metallic material selectively to the material of the first dielectric material layer 10. The source electrodes 12 and the drain electrode 18 may be formed in the via-shaped cavities. The gate electrodes 15 may be formed in the pad-shaped cavities. In one embodiment, the gate electrodes 15 may have respective rectangular horizontal cross-sectional shapes. In one embodiment, top surfaces of the source electrodes 12, the gate electrodes 15, and the drain electrodes 18 may be formed within a horizontal plane including the top surface of the first dielectric material layer 10.

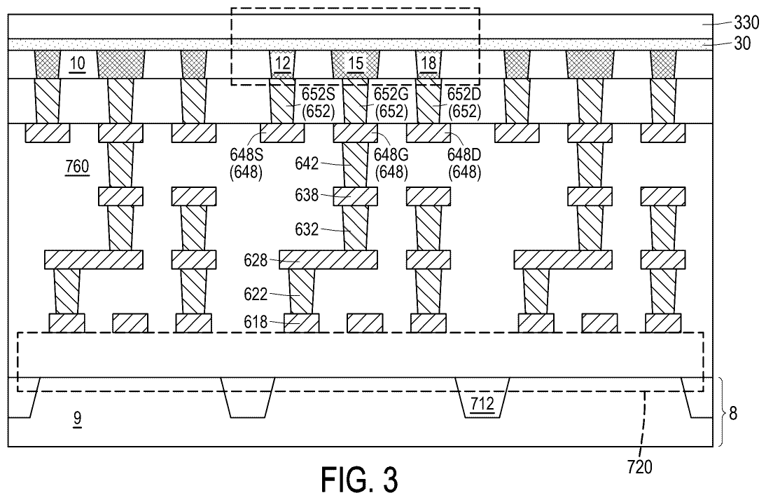

Referring to FIG. 3, a gate dielectric layer 30 may be formed over the first dielectric material layer 10. The gate dielectric layer 30 may be deposited using various deposition techniques such as chemical vapor deposition (CVD), atomic layer deposition (ALD), or physical vapor deposition (PVD). In one embodiment, the gate dielectric layer 30 may comprise a high-k dielectric material. The high-k dielectric material may include, but is not limited to, hafnium oxide, zirconium oxide, aluminum oxide, or combinations thereof. The gate dielectric layer 30 may have a thickness between 2 nm and 20 nm, although lesser or greater thicknesses may also be used. The gate dielectric layer 30 may extend over the entire top surface of the first dielectric material layer 10, and over the entire top surfaces of the source electrodes 12, the gate electrodes 15, and the drain electrodes 18.

A hard mask layer 330 may be formed over the gate dielectric layer 30. The hard mask layer 330 may serve as a protective layer during subsequent processing steps and may be used to define openings for contact via structures. The hard mask layer 330 comprises a dielectric material that may be subsequently removed selectively to the material of the gate dielectric layer 30. In one embodiment, the hard mask layer 330 may comprise materials such as silicon nitride, silicon oxynitride, or silicon carbide. The hard mask layer 330 may be deposited using techniques similar to those used for the gate dielectric layer 30, such as CVD, ALD, or PVD. The thickness of the hard mask layer 330 may be in a range from 5 nm to 50 nm, although lesser or greater thicknesses may also be used. The hard mask layer 330 may be deposited as a blanket (i.e., unpatterned) material layer directly on the gate dielectric layer 30.

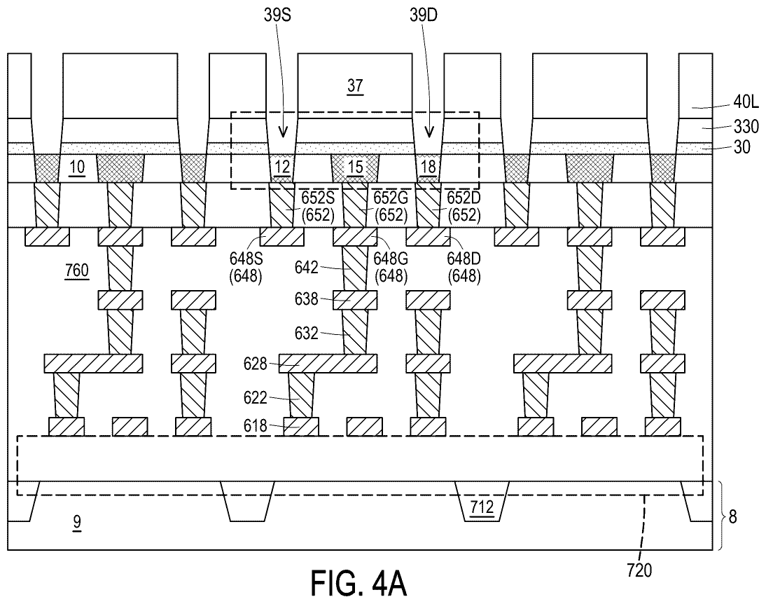

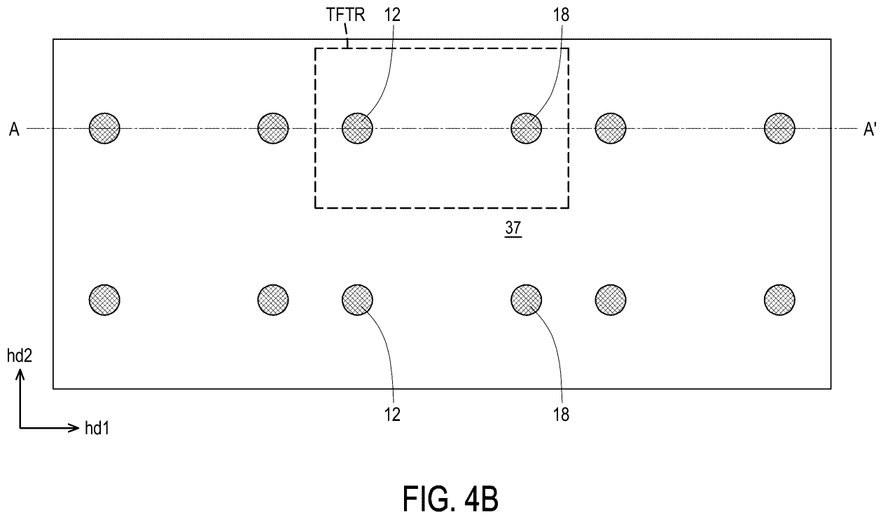

Referring to FIGS. 4A and 4B, a photoresist layer 37 may be formed over the hard mask layer 330. The photoresist layer 37 may be patterned to define openings in areas of the source electrodes 12 and the drain electrodes 18, i.e., in areas having areal overlaps with the source electrodes 12 and the drain electrodes 18. Generally, the areal overlap between each opening in the photoresist layer 37 and a respective underlying one of the source electrodes 12 and the drain electrodes 18 may be in a range from 80% to 100% of the areas of the respective opening in the photoresist layer 37.

In one embodiment, an anisotropic etch process may be performed to form a source-side opening 39S and a drain-side opening 39D through the hard mask layer 330 and the gate dielectric layer 30 within each thin film transistor region TFTR. The anisotropic etch process may sequentially etch the material of the hard mask layer 330 and the material of the gate dielectric layer 30 selectively to the material(s) of the source electrodes 12 and the drain electrodes 18 using the photoresist layer 37 as an etch mask. The source-side opening 39S and the drain-side opening 39D may be formed such that the source-side opening 39S has a first areal overlap with the source electrode 12 and the drain-side opening 39D has a second areal overlap with the drain electrode 18. Each source-side opening 39S and each drain-side opening 39D may be formed through the layer stack of the hard mask layer 330 and the gate dielectric layer 30.

A top surface of a source electrode 12 may be physically exposed underneath each source-side opening 39S, and a top surface of a drain electrode 18 may be physically exposed underneath each drain-side opening 39D. In one embodiment, the entirety of the bottom surface of each source-side opening 39S may be a top surface segment of a respective underlying source electrode 12, and the entirety of the bottom surface of each drain-side opening 39D may be a top surface segment of a respective underlying drain electrode 18. In one embodiment, the bottom periphery of each source-side opening 39S may be laterally offset inward relative to the periphery of the top surface of a respective underlying source electrode 12, and the bottom periphery of each drain-side opening 39D may be laterally offset inward relative to the periphery of the top surface of a respective underlying drain electrode 18. The photoresist layer 37 may be subsequently removed, for example, by ashing.

Referring collectively to FIGS. 3, 4A, and 4B, a layer stack of a gate dielectric layer 30 and a hard mask layer 330 may be formed over the source electrode 12, the drain electrode 18, and a gate electrode 15 within each thin film transistor region TFTR, and a source-side opening 39S and a drain-side opening 39D may be formed through the hard mask layer 330 and the gate dielectric layer 30 within each thin film transistor region TFTR such that the source-side opening 39S has a first areal overlap with the source electrode 12 and the drain-side opening 39D has a second areal overlap with the drain electrode 18.

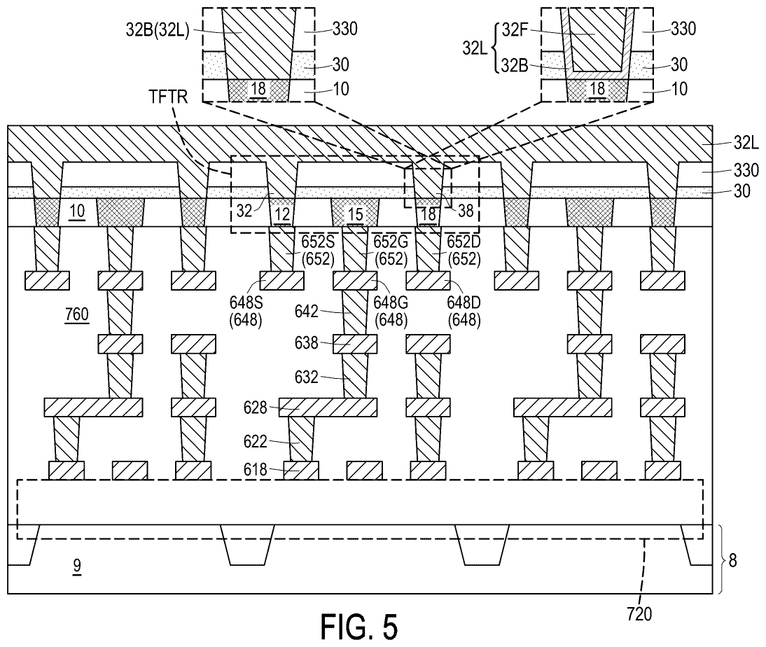

Referring to FIG. 5, a metallic material layer 32L may be deposited in the source-side opening 39S and the drain-side opening 39D and over the hard mask layer 330. The metallic material layer 32L comprises at least one metallic material.

In one embodiment, the metallic material layer 32L may include a metallic barrier liner 32B and a metallic fill material portion 32F. The metallic barrier liner 32B comprises a metallic material that prevents diffusion of the metallic fill material into surrounding dielectric materials and/or to improve adhesion of the metallic fill material. In one embodiment, the metallic barrier liner 32B comprises a conductive metallic nitride material such as TiN, TaN, WN, or MoN. The metallic barrier liner 32B may be conformally deposited to line the sidewalls and bottom surfaces of the source-side opening 39S and the drain-side opening 39D. The thickness of the metallic barrier liner 32B may be in a range from 3 nm to 30 nm, although lesser or greater thicknesses may also be used. The metallic fill material portion 32F may be deposited over the metallic barrier liner 32B so the entire volume of each of the source-side openings 39S and the drain-side openings 39D is filled with the combination of the metallic barrier liner 32B and the metallic fill material portion 32F. In one embodiment, the metallic fill material portion 32F may comprise W, Cu, Al, Mo, Co, Ru, Ti, or Ta.

In an alternative embodiment, the metallic material layer 32L may consist of a metallic barrier liner 32B. In this embodiment, the thickness of the metallic barrier liner 32B may be selected such that the entire volume of each of the source-side openings 39S and the drain-side openings 39D is filled with the metallic barrier liner 32B. It is noted that FIG. 5 illustrates the alternative embodiment metallic material layer 32L composition that may be deposited in the drain side opening 39D. One of ordinary skill in the art would understand that these alternative metallic material layer 32L compositions may also be deposited in the source-side opening 39S.

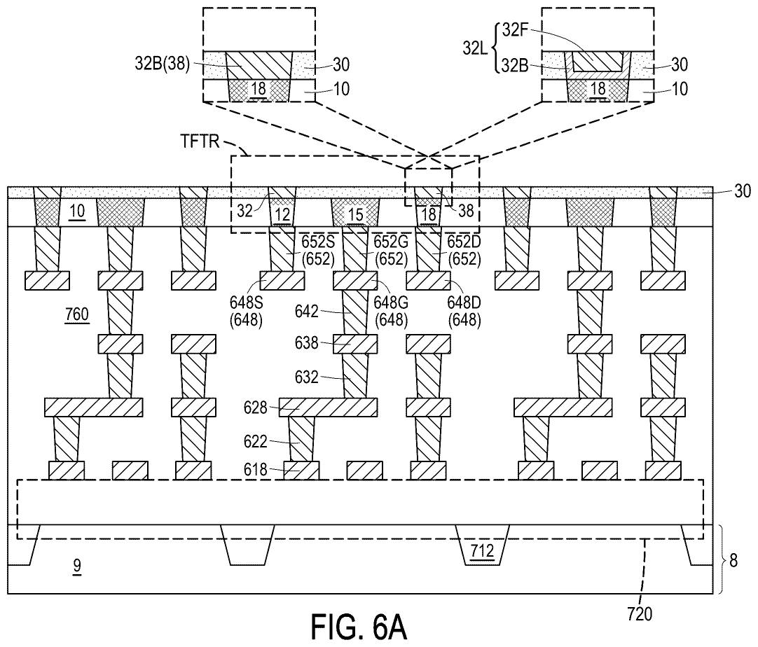

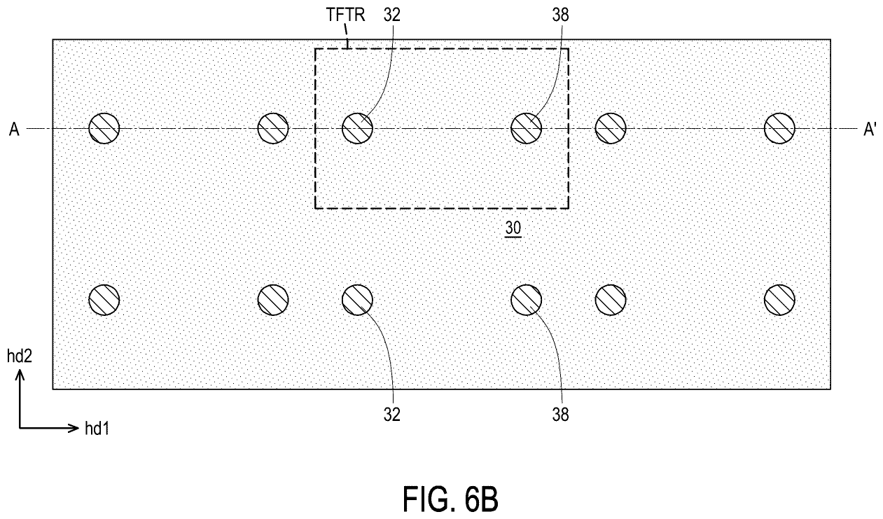

Referring to FIGS. 6A and 6B, portions of the metallic material layer 32L and the hard mask layer 330 may be removed from above the horizontal plane including the top surface of gate dielectric layer 30 by performing a chemical mechanical polishing (CM P) process. The removal of the materials of the metallic material layer 32L and the hard mask layer 330 during the CM P process may be performed selectively to the material of the gate dielectric layer 30. In other words, the chemicals and the slurry that is used during the CM P process may be selected such that the CM P process removes the materials of the metallic material layer 32L and the hard mask layer 330, while suppressing, and/or minimizing, collateral removal of the material of the gate dielectric layer 30.

Remaining portions of the metallic material layer 32L located in the source-side openings 39S constitute source contact via structures 32. Remaining portions of the metallic material layer 32L located in the drain-side openings 39D constitute drain contact via structures 38. The source contact via structures 32 and the drain contact via structures 38 have top surfaces within, or in proximity to, a horizontal plane including the top surface of the gate dielectric layer 30. Each of the source contact via structures 32 and the drain contact via structures may comprise a respective combination of a metallic barrier liner 32B and a metallic fill material portion 32F. Alternatively, each of the source contact via structures 32 and the drain contact via structures may consist of a respective metallic fill material portion 32F.

Referring collectively to FIGS. 5 and 6A, 6B, within each thin film transistor region TFTR, a source contact via structure 32 and a drain contact via structure 38 may be formed through the gate dielectric layer 30 and on a source electrode 12 and a drain electrode 18, respectively. The source contact via structure 32 and the drain contact via structure 38 for each thin film transistor may be formed by depositing and recessing at least one metallic material in the source-side opening 39S and the drain-side opening 39D in each thin film transistor region TFTR. The at least one metallic material and the hard mask layer 330 may be removed by performing a chemical mechanical polishing process. Remaining portions of the at least one metallic material within lower portions of the source-side opening 39S and the drain-side opening 39D through the gate dielectric layer 30 comprise a source contact via structure 32 and a drain contact via structure 38.

The removal of the hard mask layer 330 exposes the top surface of the gate dielectric layer 30. Further, the top surfaces of the source contact via structure 32 and the drain contact via structure 38 may also be exposed. Generally, the top surfaces of the source contact via structure 32 and the drain contact via structure 38 may be formed within, or in proximity to, the horizontal plane including the top surface of the gate dielectric layer 30. In one embodiment, the top surfaces of the source contact via structure 32 and the drain contact via structure 38 may be formed within the horizontal plane including the top surface of the gate dielectric layer 30. In another embodiment, the top surfaces of the source contact via structure 32 and the drain contact via structure 38 may be formed above the horizontal plane including the top surface of the gate dielectric layer 30. In one embodiment, the top surfaces of the source contact via structure 32 and the drain contact via structure 38 may be formed below the horizontal plane including the top surface of the gate dielectric layer 30. The vertical distance between the horizontal plane including the top surfaces of the source contact via structure 32 and the drain contact via structure 38 and the horizontal plane including the top surface of the gate dielectric layer 30 may be 0 or greater than 0, and may be less than the thickness of the gate dielectric layer 30.

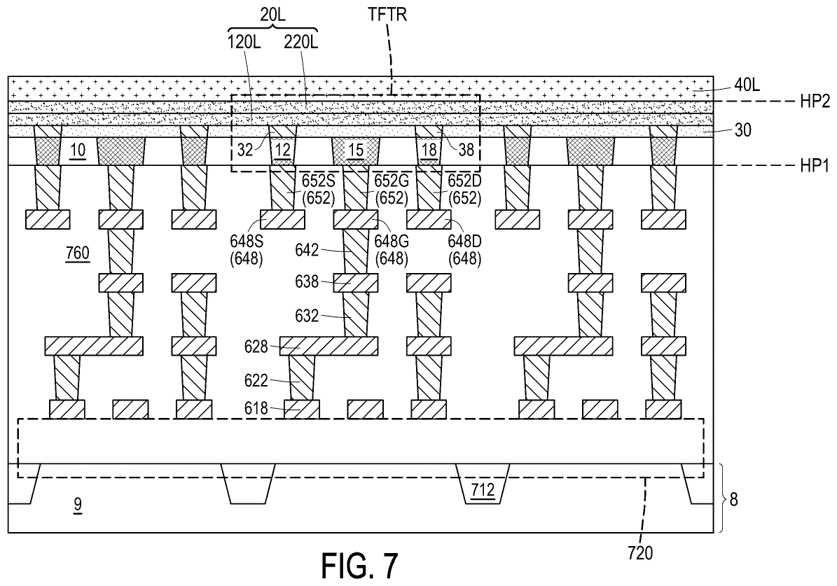

Referring to FIG. 7, a semiconducting metal oxide material layer 20L may be deposited over the gate dielectric layer 30, the source contact via structure 32, and the drain contact via structure 38. The semiconducting metal oxide material layer 20L may be deposited directly on top surfaces of the gate dielectric layer 30, the source contact via structure 32, and the drain contact via structure 38. The semiconducting metal oxide material layer 20L comprises at least one semiconducting metal oxide material. Each semiconducting metal oxide material may be an amorphous oxide semiconductor (AOS) or a crystalline oxide semiconductor (COS). The thickness of the semiconducting metal oxide material layer 20L may be in a range from 1 nm to 30 nm, such as from 2 nm to 30 nm, although lesser or greater thicknesses may also be used. The semiconducting metal oxide material layer 20L may be deposited using various deposition techniques such as atomic layer deposition (ALD), chemical vapor deposition (CVD), or physical vapor deposition (PVD).

In one embodiment, the semiconducting metal oxide material layer 20L comprises at least one semiconducting metal oxide material each providing a respective carrier concentration in a range from 1.0×10¹²/cm³ to 1.0×10¹⁹/cm³, and is capable of providing a higher carrier concentration in a range from 1.0×10¹⁸/cm³ to 1.0×10²¹/cm³ upon subsequent doping with electrical dopants (which may be p-type dopants or n-type dopants). In some embodiment, the dose of the electrical dopants may be selected such that the implanted portions of the active layers have electrical conductivity in a range from 1.0 S/m to 1.0×10⁵ S/m, and preferably in a range from 1.0×10³ S/m to 1.0×10⁵ S/m. Exemplary semiconducting metal oxide materials that may be used for the semiconducting metal oxide material layer 20L include, but are not limited to, quaternary compounds such as indium gallium zinc oxide (IGZO), indium tungsten zinc oxide, tin gallium zinc oxide, and tin tungsten zinc oxide, and ternary compounds such as indium gallium oxide, indium oxide tungsten, tin gallium oxide, and tin tungsten oxide. In one embodiment, the semiconducting metal oxide material(s) of the semiconducting metal oxide material layer 20L may comprise a zinc-containing quaternary semiconducting compound such as indium gallium zinc oxide (IGZO), indium tungsten zinc oxide, tin gallium zinc oxide, or tin tungsten zinc oxide. In another embodiment, the semiconducting metal oxide material of the semiconducting metal oxide material layer 20L may comprise a ternary compound such as indium gallium oxide, indium oxide tungsten, tin gallium oxide, or tin tungsten oxide.

In one embodiment, the semiconducting metal oxide material layer 20L may include a layer stack of a first semiconducting metal oxide material layer 120L and a second semiconducting metal oxide material layer 220L. In this embodiment, the first semiconducting metal oxide material layer 120L may comprise a first semiconducting metal oxide material providing high charge carrier density and high on-current, and the second semiconducting metal oxide material layer 220L may comprise a second semiconducting metal oxide material providing low charge carrier density and low leakage current. In one embodiment, the thickness of the first semiconducting metal oxide material layer 120L may be in a range from 10% to 50% of the thickness of the semiconducting metal oxide material layer 20L. In one embodiment, the thickness of the second semiconducting metal oxide material layer 220L is greater than the thickness of the first semiconducting metal oxide material layer 120L.

In one embodiment, different device regions can include different semiconducting metal oxide material compositions for the semiconducting metal oxide material layer 20L. The selection of n-type or p-type composition within the semiconducting metal oxide material layer 20L in each device region can be made such that, during subsequent processing steps, an n-type semiconducting metal oxide material can be subsequently heavily doped with n-type dopants to form n++ type (i.e., heavily-doped n-type) source regions and drain regions, while a p-type semiconducting metal oxide material can be subsequently heavily doped with p-type dopants to form p++ type (i.e., heavily-doped p-type) source regions and drain regions. The heavily doped source region and the heavily doped drain regions have a carrier concentration (hereafter referred to as a high carrier concentration) that is greater than the carrier concentration of the respective semiconducting metal oxide material prior to introduction of the dopants (hereafter referred to as a low carrier concentration). Specifically, the ratio of the high carrier concentration to the low carrier concentration within the semiconducting metal oxide material may be in the range of 1 to 10⁷, and preferably in the range of 10⁴ to 10⁷. Selecting a ratio within this range facilitates enhanced control of the threshold voltage, stable device operation, and improved reliability.

An ion implantation mask material layer 40L may be deposited over the semiconducting metal oxide material layer 20L by depositing at least one insulating material. The at least one insulating material of the ion implantation mask material layer 40L may comprise silicon oxide, silicon nitride, silicon carbide nitride, or silicon oxynitride. The ion implantation mask material layer 40L may be formed as a blanket (unpatterned) material layer deposited over the entire surface of the semiconducting metal oxide material layer 20L. The thickness of the ion implantation mask material layer 40L may be in a range from 5 nm to 100 nm, such as from 10 nm to 50 nm, although lesser or greater thicknesses may also be used.

The bottom surfaces of the source contact via structures 32 and the drain contact via structures 38 are formed within a first horizontal plane HP1 that includes the top surface of the first dielectric material layer 10 and the bottom surface of the gate dielectric layer 30. The top surfaces of the source contact via structures 32 and the drain contact via structures 38 may make contact with bottom surface segments of the semiconducting metal oxide material layer 20L. As such, the top surfaces of the source contact via structures 32 and the drain contact via structures 38 are formed below a second horizontal plane HP2 that includes the top surface of the ion implantation mask material layer 40L.

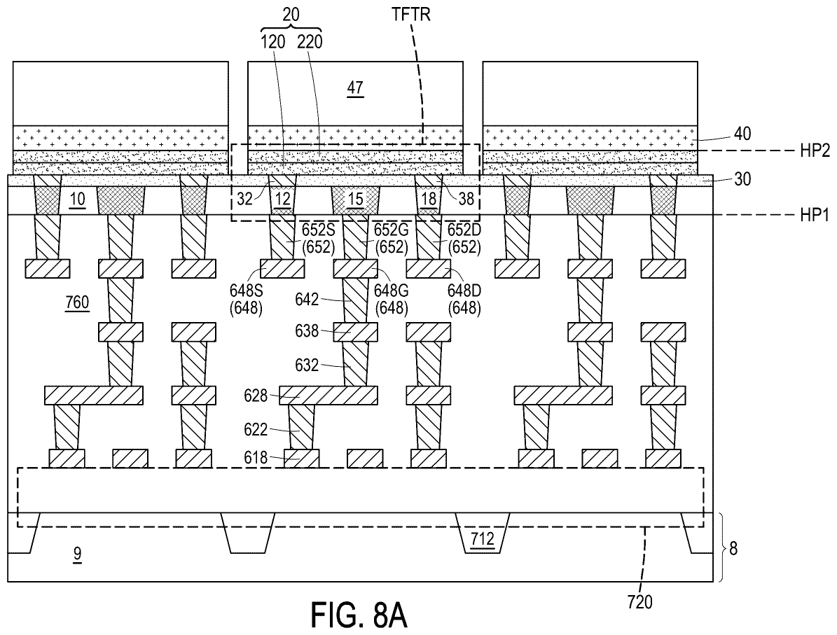

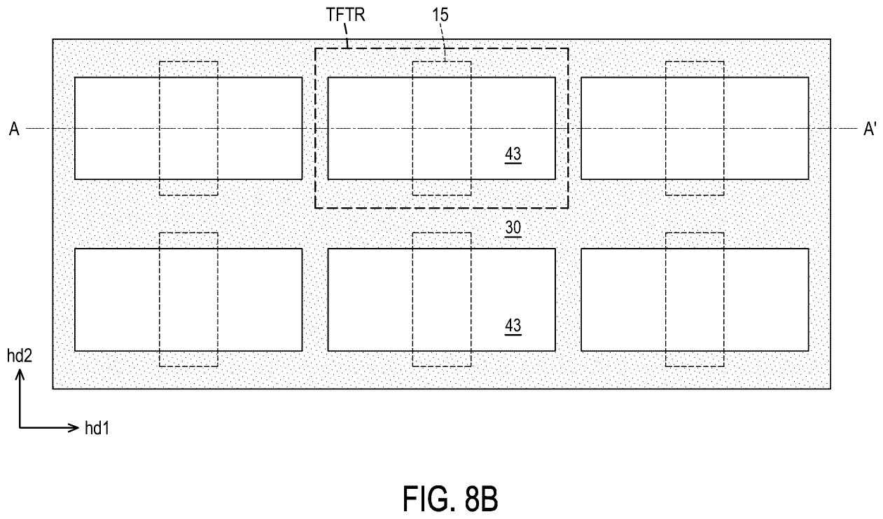

Referring to FIGS. 8A and 8B, a first photoresist layer 43 may be applied over the ion implantation mask material layer 40L, and may be lithographically patterned to cover areas in which active layers 20 are to be subsequently formed. In one embodiment, the first photoresist layer 43 may be patterned into a two-dimensional periodic array of patterned photoresist material portions. In one embodiment, each of the patterned photoresist material portions may have a respective rectangular shape having a pair of lengthwise sides that are parallel to the first horizontal direction hd1 and a pair of widthwise sides that are parallel to the second horizontal direction hd2. In one embodiment, each patterned photoresist material portion may cover the entire area of a respective underlying source contact via structure 32, the entire area of a respective underlying drain contact via structure 38, and a predominant portion, but not the entirety, of the area of a respective underlying gate electrode 15. In one embodiment, the respective underlying gate electrode 15 may have a greater lateral extent along the second horizontal direction hd2 than the lateral extent of an overlying patterned photoresist material portion. Specifically, two end portions of the respective underlying gate electrode 15 may not be covered by the overlying patterned photoresist material portion.

An anisotropic etch process may be performed to transfer the pattern in the first photoresist layer 43 through the ion implantation mask material layer 40L and the semiconducting metal oxide material layer 20L. The first photoresist layer 43 functions as a patterned etch mask for the anisotropic etch process. The anisotropic etch process etches unmasked portions of the ion implantation mask material layer 40L and the semiconducting metal oxide material layer 20L. The anisotropic etch process may be a reactive ion etch process that etches the materials of the ion implantation mask material layer 40L and the semiconducting metal oxide material layer 20L selectively to the material of the gate dielectric layer 30. For example, the chemistry of the step of the anisotropic etch process that etches the material of the semiconducting metal oxide material layer 20L may be selective to the material of the gate dielectric layer 30.

The anisotropic etch process may divide the ion implantation mask material layer 40L into a two-dimensional array of ion implantation mask layers 40′. In other words, patterned portions of the ion implantation mask material layer 40L comprise the ion implantation mask layers 40′. Further, the anisotropic etch process may divide the semiconducting metal oxide material layer 20L into a two-dimensional array of active layers 20. In other words, the patterned portions of the semiconducting metal oxide material layer 20L comprise the active layers 20. The first photoresist layer 43 may be subsequently removed, for example, by ashing.

In one embodiment, the semiconducting metal oxide material layer 20L comprises a vertical stack of a first semiconducting metal oxide material layer 120L and a second semiconducting metal oxide material layer 220L, and each active layer 20 may include a vertical stack of a first active layer 120 and a second active layer 220. In this embodiment, each first active layer 120 is a patterned portion of the first semiconducting metal oxide material layer 120L, and each second active layer 220 is a patterned portion of the second semiconducting metal oxide material layer 220L.

Within each thin film transistor region TFTR, the active layer 20 may be formed directly on an entirety of a top surface of the source contact via structure 32 and directly on an entirety of a top surface of the drain contact via structure 38. In other words, within each thin film transistor region TFTR, an entirety of the top surface of the source contact via structure 32 may be contacted by the active layer 20, and an entirety of the top surface of the drain contact via structure 38 may be contacted by the active layer 20.

Within each thin film transistor region TFTR, the ion implantation mask layer 40′ (which is a patterned portion of the ion implantation mask material layer 40L) may have the same area as the active layer 20 in a plan view. The sidewalls of the ion implantation mask layer 40′ may be vertically coincident with the sidewalls of the active layer 20. In other words, the sidewalls of the ion implantation mask layer 40′ may be located within a same set of vertical planes as the sidewalls of the active layers 20. The periphery of the top surface of the active layer 20 may coincide with the periphery of the bottom surface of the ion implantation mask layer 40′ in each thin film transistor region TFTR.

Each active layer 20 may have a rectangular shape with an active layer length along a first horizontal direction hd1 and an active layer width along a second horizontal direction hd2. In one embodiment, the gate electrode 15 may extend along the second horizontal direction hd2 and may have a greater lateral extent than the lateral extent of the active layer 20 along the second horizontal direction hd2. Each active layer 20 may be formed directly on an entirety of a top surface of the source contact via structure 32 and directly on an entirety of a top surface of the drain contact via structure 38.

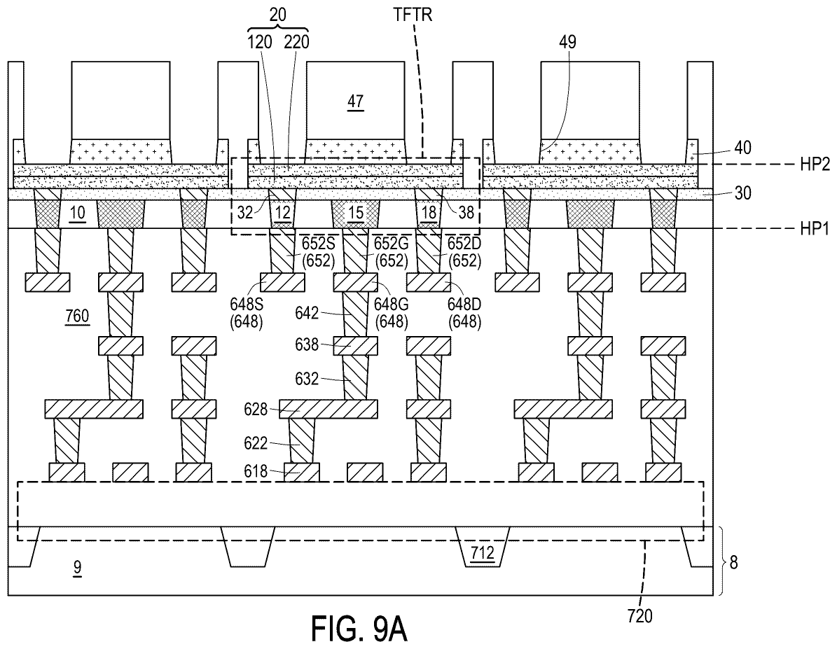

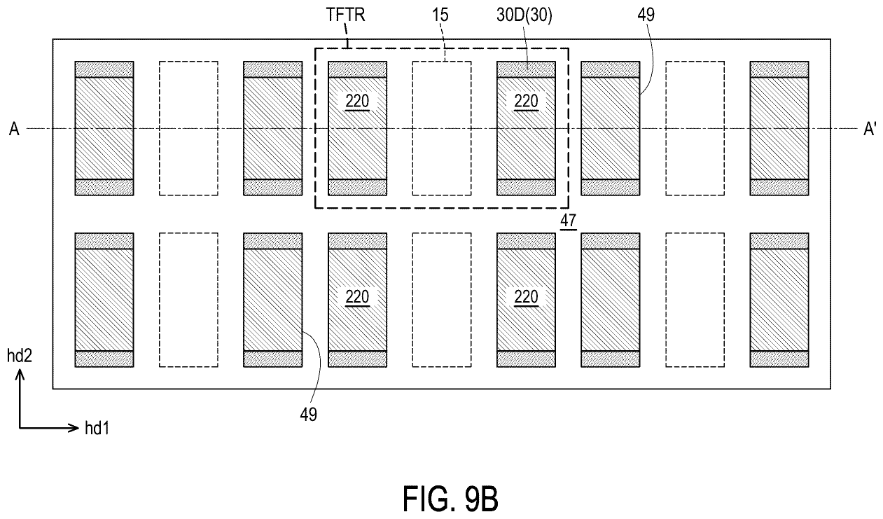

Referring to FIGS. 9A and 9B, a second photoresist layer 47 may be applied over the ion implantation mask layers 40′ and the gate dielectric layer 30, and may be lithographically patterned to form discrete openings overlying end portions of each active layer 20 that are laterally spaced apart along the first horizontal direction hd1. In one embodiment, the second photoresist layer 47 may be patterned to expose end portions of each ion implantation mask layer 40′ while covering a central portion of each ion implantation mask layer 40′ having an areal overlap with a respective underlying gate electrode 15.

An anisotropic etch process may be performed to transfer the pattern in the second photoresist layer 47 through the ion implantation mask layers 40′. The anisotropic etch process may form a pair of implantation mask openings 49 through each ion implantation mask layer 40′. Thus, the implantation mask openings 49 may be formed over end portions of the active layers 20. Each ion implantation mask layer 40′ with a respective pair of implantation mask openings 49 is herein referred to as an ion implantation mask plate 40.

In one embodiment, each active layer 20 may have a rectangular shape with an active layer length along the first horizontal direction hd1 and an active layer width along the second horizontal direction hd2. An ion implantation mask plate 40 overlies the active layer 20. Each of the pair of implantation mask openings 49 may have a respective pair of straight sidewalls that are parallel to the second horizontal direction hd2 and adjoined to two segments of the lengthwise sidewalls of the active layer 20. In this embodiment, the straight sidewalls of each implantation mask opening 49 may have the same length as the active layer width, and each ion implantation mask plate 40 may comprise a respective set of three discrete ion implantation mask material portions that are laterally spaced apart from one another along the first horizontal direction hd1.

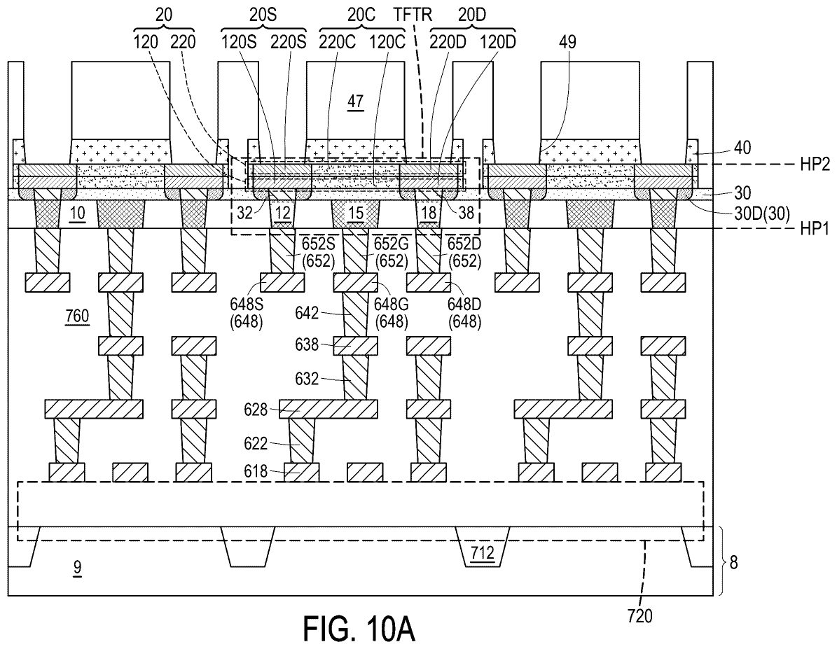

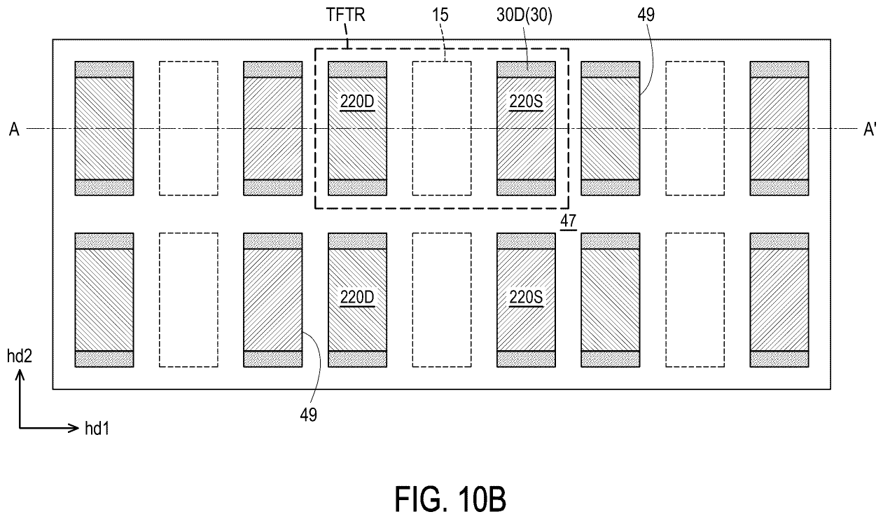

Referring to FIGS. 10A and 10B, an ion implantation process may be performed to implant electrical dopants into end portions of the active layers 20 that underlie the implantation mask openings 49. In one embodiment, the second photoresist layer 47 may be present during the ion implantation process, and the combination of the ion implantation mask plates 40 and the second photoresist layer 47 may function as an implantation mask. Alternatively, the second photoresist layer 47 may be removed, for example, by ashing prior to performing the ion implantation process. In this embodiment, the ion implantation mask plates 40 function as the implantation mask during the ion implantation process. The ion implantation process may comprise a conventional ion implantation process in which the electrical dopants are accelerated in the form of ions in an ion accelerator, and are directed into the unmasked portions of the active layers 20. Alternatively, the ion implantation process may comprise a plasma doping process in which the dopant ions are activated in a plasma, and are implanted into the unmasked portions of the active layers 20.

The implanted electrical dopants may comprise p-type dopants or n-type electrical dopants. The dose of the electrical dopants may be selected such that the implanted portions of the active layers have a carrier concentration in a range from 1.0×10¹⁸/cm³ to 1.0×10²¹/cm³. In some embodiment, the dose of the electrical dopants may be selected such that the implanted portions of the active layers have electrical conductivity in a range from 1.0 S/m to 1.0×10⁵ S/m, and preferably in a range from 1.0×10³ S/m to 1.0×10⁵ S/m. The implanted portions of the active layers 20 are converted into source regions 20S and drain regions 20D. A source region 20S and a drain region 20D may be formed within each active layer 20. Further, the unimplanted portion of each active layer 20 which is located between the source region 20S and the drain region 20D of the respective active layer 20 constitutes a channel region 20C.

Generally, the ion implantation process may use the ion implantation mask plates 40 as an implantation mask. The electrical dopants may be implanted through the implantation mask openings 49 in the ion implantation mask plates 40. The source regions 20S and the drain regions 20D may be formed in implanted portions of the active layers 20.

In one embodiment, each active layer 20 may comprise a vertical stack of a first active layer 120 and a second active layer 220. In this embodiment, each source region 20S may include a respective vertical stack of a first source region 120S and a second source region 220S, and each drain region 20D may include a respective vertical stack of a first drain region 120D and a second drain region 220D. Each channel region 20C may include a respective vertical stack of a first channel region 120C and a second channel region 220C. Each first source region 120S is an implanted portion of a respective first active layer 120. Each first drain region 120D is an implanted portion of a respective first active layer 120. Each first channel region 120C is an implanted portion of a respective first active layer 120. Each second source region 220S is an implanted portion of a respective second active layer 220. Each second drain region 220D is an implanted portion of a respective second active layer 220. Each second channel region 220C is an implanted portion of a respective second active layer 220.

Portions of the gate dielectric layer 30 that are proximal to the source regions 20S and the drain regions 20D may be collaterally doped during the ion implantation process to form doped gate dielectric portions 30D. As such, the doped gate dielectric portions 30D include all elemental species within the material composition of the gate dielectric layer 30 prior to the ion implantation process, and further includes the elemental species of the dopant atoms.

Generally speaking, end portions of each active layer 20 may be converted into a source region 20S and a drain region 20D by implanting electrical dopants into the end portions. An unimplanted portion of the active layer 20 located between the source region 20S and the drain region 20D comprises a channel region 20C. Thus, each active layer comprises a combination of a source region 20S, a drain region 20D, and a channel region 20C. The second photoresist layer 47 may be subsequently removed, for example, by ashing. A thin film transistor is formed in each thin film transistor region TFTR.

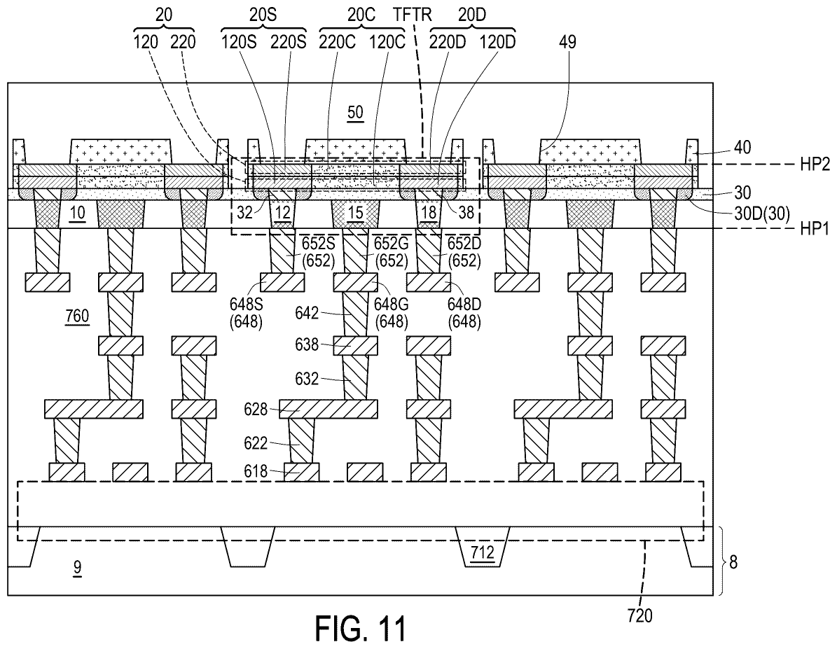

Referring to FIG. 11, a second dielectric material layer 50 may be deposited over the ion implantation mask plates 40 and exposed regions of the active layers 20. The second dielectric material layer 50 may comprise an insulating material such as silicon oxide, silicon nitride, or silicon oxynitride. In some embodiments, the second dielectric material layer 50 may be deposited using chemical vapor deposition (CVD), atomic layer deposition (ALD), or physical vapor deposition (PVD) techniques.

The second dielectric material layer 50 may be deposited directly on all sidewalls of the implantation mask openings 49, top surface segments of the source regions 20S, top surface segments of the drain regions 20D, and top surfaces of the ion implantation mask plates 40. In one embodiment, the second dielectric material layer 50 may be deposited directly on sidewalls of the ion implantation mask plates 40, sidewalls of the active layers 20, and surface segments of the top surface of the gate dielectric layer 30 located between neighboring pairs of active layers 20. In one embodiment, sidewalls of the active layers 20 contacted by the second dielectric material layer 50 include sidewalls of the source regions 20S, sidewalls of the drain regions 20D, and sidewalls of the channel regions 20C.

The second dielectric material layer 50 provides electrical isolation between adjacent thin film transistors. Further, the second dielectric material layer 50 may also act as a protective layer or a passivation layer for the thin film transistors. All electrical nodes of the thin film transistors are electrically contacted from below. For example, each source region 20S is contacted by a respective underlying source contact via structure 32, each drain region 20D is contacted by a respective underlying drain contact via structure 38, and each gate electrode 15 is contacted by a respective underlying gate connection metal via structure 652G.

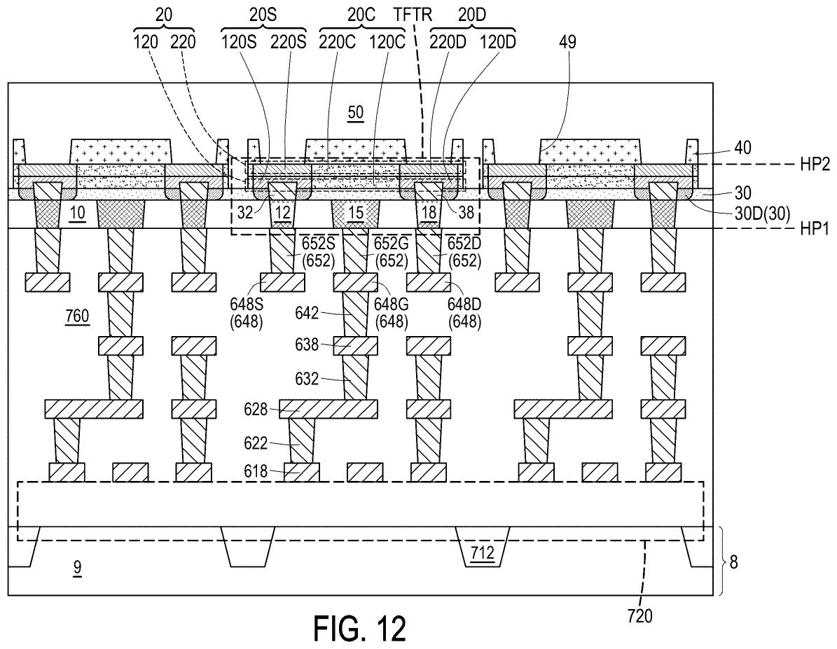

Referring to FIG. 12, a first alternative configuration of the exemplary structure may be derived from the exemplary structure illustrated in FIG. 11 by underpolishing the source contact via structures 32 and the drain contact via structures 38 relative to the gate dielectric layer 30 at the CM P processing step described with reference to FIG. 6. In this embodiment, top surfaces of the source contact via structures 32 and the drain contact via structures 38 may be formed above the horizontal plane including the interface between the gate dielectric layer 30 and the active layers 20. The vertical distance between the top surfaces of the source contact via structures 32 and the drain contact via structures 38 and the horizontal plane including the interface between the gate dielectric layer 30 and the active layers 20 may be in a range from 0.1 nm to 10 nm, such as from 0.3 nm to 3 nm, although lesser or greater vertical distances may also be used.

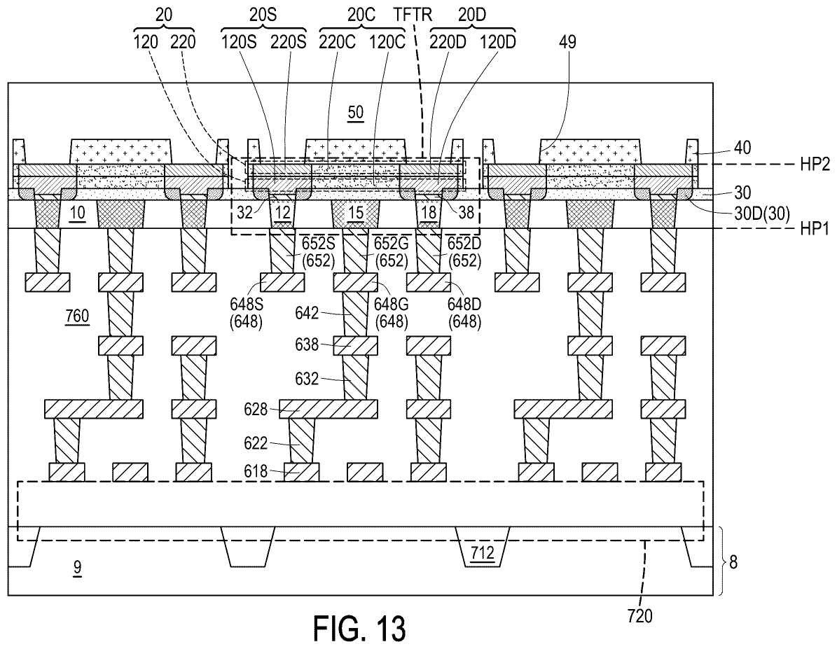

Referring to FIG. 13, a second alternative configuration of the exemplary structure may be derived from the exemplary structure illustrated in FIG. 11 by overpolishing the source contact via structures 32 and the drain contact via structures 38 relative to the gate dielectric layer at the CM P processing step described with reference to FIG. 6. In this embodiment, top surfaces of the source contact via structures 32 and the drain contact via structures 38 may be formed below the horizontal plane including the interface between the gate dielectric layer 30 and the active layers 20. The vertical distance between the top surfaces of the source contact via structures 32 and the drain contact via structures 38 and the horizontal plane including the interface between the gate dielectric layer 30 and the active layers 20 may be in a range from 0.1 nm to 10 nm, such as from 0.3 nm to 3 nm, although lesser or greater vertical distances may also be used.

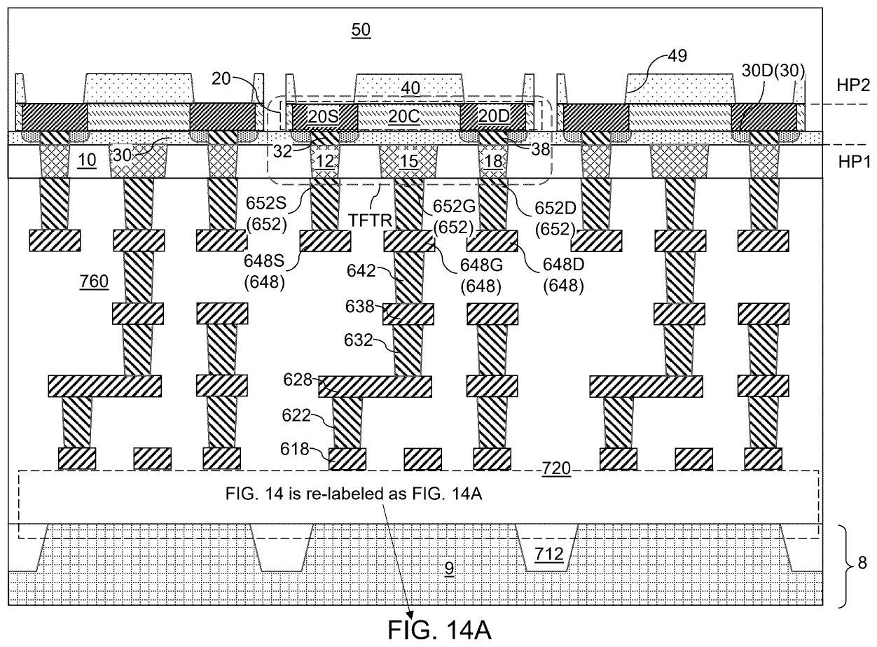

Referring to FIG. 14, a third alternative configuration of the exemplary structure may be derived from the exemplary structure described with reference to FIG. 10, or the alternative configurations therefrom described with reference to FIGS. 11 and 12 by using a single semiconducting metal oxide material for the semiconducting metal oxide material layer 20L at the processing steps described with reference to FIG. 7. In this embodiment, each active layer 20 may have a uniform material composition throughout, and the charge carrier properties of the semiconducting metal oxide material in each channel region 20C may be uniform throughout the entire volume of each channel region 20.

Referring collectively to FIGS. 1A-14 and according to an aspect of the present disclosure, a semiconductor structure may be provided. The semiconductor structure includes a gate electrode 15, a source electrode 12, and a drain electrode 18 located within a first dielectric material layer 10. A gate dielectric layer 30 may be formed overlying the first dielectric material layer 10. The structure may further comprise a source contact via structure 32 vertically extending through the gate dielectric layer 30 and contacting the source electrode 12, as well as a drain contact via structure 38 vertically extending through the gate dielectric layer 30 and contacting the drain electrode 18. An active layer 20 may be formed overlying the gate dielectric layer 30.

In one embodiment, the entirety of a top surface of the source contact via structure 32 may be in contact with the active layer 20. Similarly, the entirety of a top surface of the drain contact via structure 38 may be contacted by the active layer 20.

In one embodiment, the semiconductor structure may additionally include an ion implantation mask plate 40 overlying the active layer 20. This ion implantation mask plate 40 may comprise a pair of implantation mask openings 49 therethrough. In certain embodiments, the active layer 20 may include a source region 20S and a drain region 20D, each of which may be positioned beneath a respective one of the pair of implantation mask openings 49.

In one embodiment, a second dielectric material layer 50 may be present. This layer may be in contact with all sidewalls of the pair of implantation mask openings 49, a top surface segment of the source region 20S, a top surface segment of the drain region 20D, and a top surface of the ion implantation mask plate 40.

The semiconductor structure may be arranged such that the entire outer periphery of a top surface of the active layer 20 coincides with the entire outer periphery of a bottom surface of the ion implantation mask plate 40. Furthermore, the top surface of the source contact via structure 32 and the top surface of the drain contact via structure 38 may be situated within a horizontal plane. This plane may be positioned above a first horizontal plane HP1 that includes a bottom surface of the gate dielectric layer 30, while being located below a second horizontal plane HP2 that includes a top surface of the active layer 20.

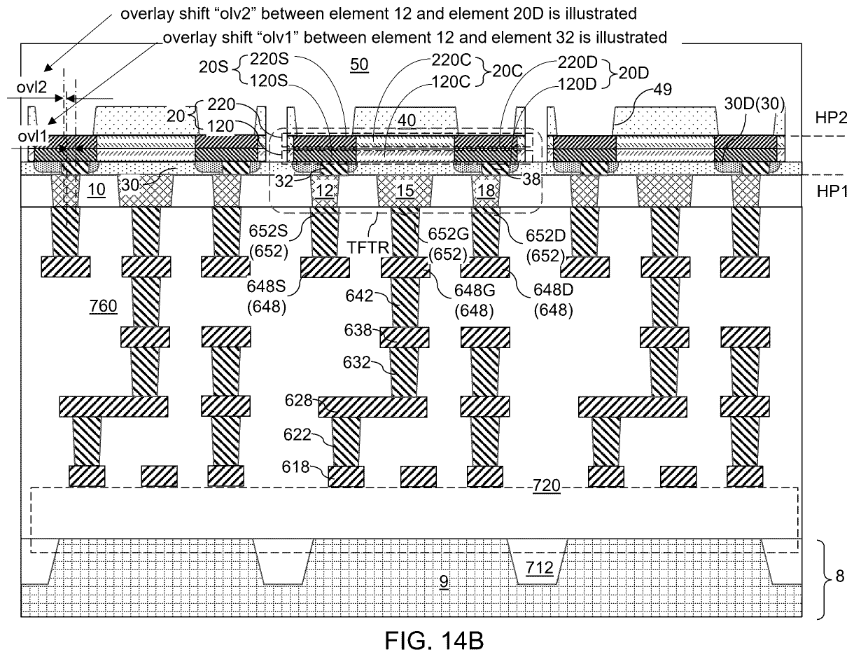

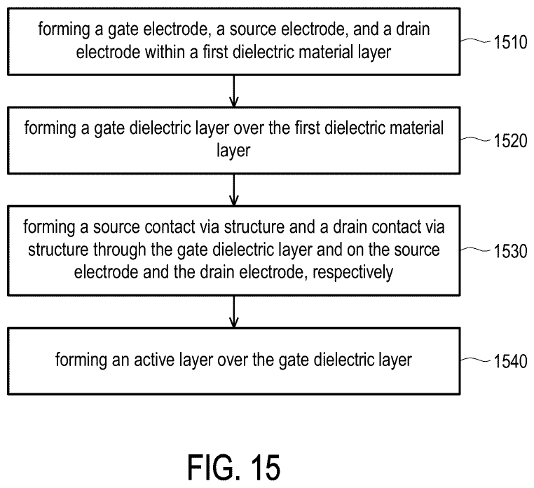

Referring to FIG. 15, a first flow chart illustrates a method of forming a semiconductor device according to an embodiment of the present disclosure.

Referring to step 1510 and FIGS. 1A-2B, a gate electrode 15, a source electrode 12, and a drain electrode 18 may be formed within a first dielectric material layer 10.

Referring to step 1520 and FIG. 3, a gate dielectric layer 30 may be formed over the first dielectric material layer 10.

Referring to step 1530 and FIGS. 4A-6B, a source contact via structure 32 and a drain contact via structure 38 may be formed through the gate dielectric layer 30 and on the source electrode 12 and the drain electrode 18, respectively. The source contact via structure 32 and the drain contact via structure 38 may be formed by depositing at least one metallic material in source-side openings 39S and drain-side openings 39D, respectively. The at least one metallic material may include a metallic barrier liner 32B and a metallic fill material portion 32F, or may consist of the metallic barrier liner 32B.

Referring to step 1540 and FIGS. 7-14, an active layer 20 may be formed over the gate dielectric layer 30. In one embodiment, the active layer 20 may be formed by depositing a semiconducting metal oxide material layer 20L over the gate dielectric layer 30, the source contact via structure 32, and the drain contact via structure 38. The semiconducting metal oxide material layer 20L may comprise a first semiconducting metal oxide material layer 120L and a second semiconducting metal oxide material layer 220L. The semiconducting metal oxide material layer 20L may be patterned to form the active layer 20. The active layer 20 may include a channel region 20C between a source region 20S and a drain region 20D. The source region 20S and the drain region 20D may be formed by implanting electrical dopants into end portions of the active layer 20.

In one embodiment, the method may further include the step of converting end portions of the active layer into a source region 20S and a drain region 20D by implanting electrical dopants into the end portions, wherein an unimplanted portion of the active layer 20 located between the source region 20S and the drain region 20D comprises a channel region 20C. In one embodiment, the method may further include the steps of forming an ion implantation mask plate 40 including a pair of implantation mask openings over the end portions of the active layer 20; and performing an ion implantation process that implants said electrical dopants into the end portions of the active layer 20 using the ion implantation mask plate 40 as an implantation mask, whereby the end portions of the active layer 20 may be converted into a source region 20S and a drain region 20D.

In one embodiment, the ion implantation mask plate 40 comprises an insulating material; and the method comprises depositing a second dielectric material layer 50 over the ion implantation mask plate 40. In one embodiment, the second dielectric material layer 50 may be deposited on each sidewall of the ion implantation mask layer, on a top surface of the ion implantation mask plate 40, on a top surface segment of the source region 20S, and on a top surface segment of the drain region 20D.

In one embodiment, the method may further include the steps of depositing a semiconducting metal oxide material layer 20 over the gate dielectric layer 30; depositing a ion implantation mask material layer 40 over the semiconducting metal oxide material layer 20; and patterning the ion implantation mask material layer and the semiconducting metal oxide material 20 layer using a patterned etch mask, wherein a patterned portion of the semiconducting metal oxide material layer comprises the active layer.

In one embodiment, a patterned portion of the ion implantation mask material layer comprises an ion implantation mask layer having a same area as the active layer in a plan view; and the method comprises forming a pair of implantation mask openings through the ion implantation mask layer, whereby the ion implantation mask plate 40 is formed. In one embodiment, the active layer 20 has a rectangular shape with an active layer length along a first horizontal direction and an active layer width along a second horizontal direction; and each of the pair of implantation mask openings has a respective pair of sidewalls that are parallel to the second horizontal direction and adjoined to two segments of lengthwise sidewalls of the active layer 20.

In one embodiment, the method may include the steps of forming a hard mask layer over the gate dielectric layer; forming a source-side opening and a drain-side opening through the hard mask layer and the gate dielectric layer 30 such that the source-side opening has a first areal overlap with the source electrode 12 and the drain-side opening has a second areal overlap with the drain electrode 18; and depositing and recessing at least one metallic material in the source-side opening and the drain-side opening, wherein remaining portions of the at least one metallic material comprise the source contact via structure 32 and the drain contact via structure 38.

In one embodiment, the method may further include the steps of removing the hard mask layer selectively to the gate dielectric layer 30, the source contact via structure 32, and the drain contact via structure 38; depositing a semiconducting metal oxide material layer 20 on top surfaces of the gate dielectric layer 30, the source contact via structure 32, and the drain contact via structure 38; and patterning the semiconducting metal oxide material layer 20, wherein a patterned portion of the semiconducting metal oxide material layer comprise the active layer.

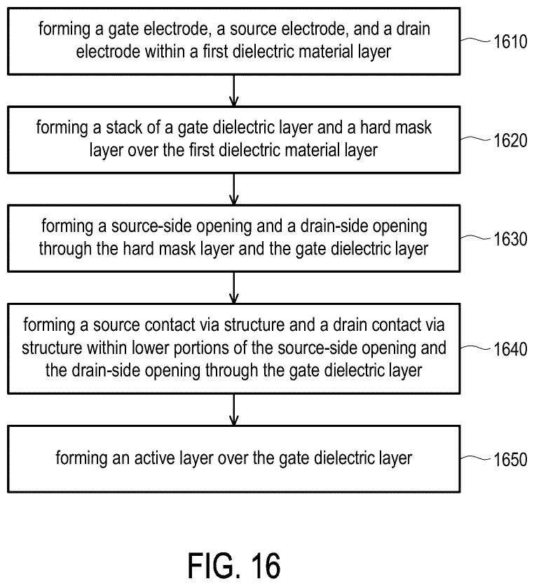

Referring to FIG. 16, a second flow chart illustrates a method of forming a semiconductor device according to an embodiment of the present disclosure.

Referring to step 1610 and FIGS. 1A-2B, a gate electrode 15, a source electrode 12, and a drain electrode 18 may be formed within a first dielectric material layer 10.

Referring to step 1620 and FIG. 3, a stack of a gate dielectric layer 30 and a hard mask layer 330 may be formed over the first dielectric material layer 10.

Referring to step 1630 and FIGS. 4A and 4B, a source-side opening 39S and a drain-side opening 39D may be formed through the hard mask layer 330 and the gate dielectric layer 30. The source-side opening 39S may have a first areal overlap with the source electrode 12, and the drain-side opening 39D may have a second areal overlap with the drain electrode 18.

Referring to step 1640 and FIGS. 5-6B, a source contact via structure 32 and a drain contact via structure 38 are formed within lower portions of the source-side opening 39S and the drain-side opening 39D through the gate dielectric layer 30. In one embodiment, the source contact via structure 32 and the drain contact via structure 38 may be formed by depositing at least one metallic material in the source-side opening 39S and the drain-side opening 39D and over the hard mask layer 330. The at least one metallic material may include a metallic barrier liner 32B and a metallic fill material portion 32F.

A first portion of the at least one metallic material may be removed from above a horizontal plane including a top surface of the hard mask layer 330. Second portions of the at least one metallic material may be removed from within upper portions of the source-side opening 39S and the drain-side opening 39D through the hard mask layer 330. Remaining portions of the at least one metallic material within lower portions of the source-side opening 39S and the drain-side opening 39D through the gate dielectric layer 30 may comprise the source contact via structure 32 and the drain contact via structure 38.

Referring to step 1650 and FIGS. 7-14, an active layer 20 is formed over the gate dielectric layer 30. In some embodiments, the active layer 20 may be formed directly on an entirety of a top surface of the source contact via structure 32 and directly on an entirety of a top surface of the drain contact via structure 38.

In one embodiment, the hard mask layer 330 may be removed selectively to the gate dielectric layer 30, the source contact via structure 32, and the drain contact via structure 38. A semiconducting metal oxide material layer may be deposited over the gate dielectric layer 30 after formation of the source contact via structure 32 and the drain contact via structure 38. An ion implantation mask material layer may be deposited over the semiconducting metal oxide material layer.

The ion implantation mask material layer and the semiconducting metal oxide material layer may be patterned using a patterned etch mask. A patterned portion of the semiconducting metal oxide material layer may comprise the active layer 20, and a patterned portion of the ion implantation mask material layer may comprise an ion implantation mask layer. A pair of implantation mask openings 49 may be formed through the ion implantation mask layer. Electrical dopants may be implanted through the pair of implantation mask openings 49 in the ion implantation mask layer, whereby a source region 20S and a drain region 20D may be formed in implanted portions of the active layer 20.

Generally, embodiments of the present disclosure provide thin-film transistors with enhanced performance characteristics and reduced defects. The semiconductor structures described herein may achieve high carrier mobility while maintaining low off-state current.

The thin film transistors of the present disclosure may include fewer defects compared to conventional structures. In some aspects, the fabrication process may minimize damage to the semiconducting metal oxide material of the active layers 20. The channel-last approach used in forming the thin film transistors may reduce exposure of the active layer 20 to potentially damaging processes. By forming the source contact via structure 32 and drain contact via structure 38 prior to depositing the semiconducting metal oxide material layer 20L, the active regions may be protected from etching and deposition steps that could introduce defects. In some embodiments, the only ion implantation process that directly affects the active layer 20 may be the implantation used to form the source regions 20S and drain regions 20D. This targeted implantation process may allow for precise control over doping while minimizing collateral damage to other portions of the active layer 20, particularly the channel region 20C.

The use of the ion implantation mask plate 40 with implantation mask openings 49 may further protect portions of the active layer 20 during the implantation process. This masking approach may help confine the implantation effects to the intended source and drain regions, potentially reducing unintended damage or doping in the channel region. Additionally, the formation of the gate dielectric layer 30 prior to the deposition of the active layer 20 may provide a protective barrier, potentially shielding the active layer from underlying process-induced defects or contaminants. By minimizing exposure to potentially damaging processes and carefully controlling the necessary implantation steps, the thin film transistors formed according to the present disclosure may exhibit reduced defects in the semiconducting metal oxide material of the active layers 20. This reduction in defects may contribute to the enhanced performance characteristics observed in these devices. By using a channel-last fabrication approach, these structures may be integrated into back-end-of-line (BEOL) processes with reduced complications related to thermal budget constraints and potential damage to underlying layers.

The methods disclosed for forming the semiconductor device may result in more consistent performance and improved reliability. The use of a gate dielectric layer, carefully formed source and drain contact via structures, and a patterned active layer may reduce variations in doping levels and electrical characteristics. Furthermore, the ion implantation process described for forming source and drain regions may minimize damage to the metal oxide semiconductor channel, particularly during etching and deposition steps. As a result, the thin-film transistors formed according to the present disclosure may exhibit superior performance, reduced defects, and enhanced reliability compared to conventional structures.

The foregoing outlines features of several embodiments so that those skilled in the art may better understand the aspects of the present disclosure. Each embodiment described using the term “comprises” also inherently discloses that the term “comprises” may be replaced with “consists essentially of” or with the term “consists of” in some embodiments, unless expressly disclosed otherwise herein. Whenever two or more elements are listed as alternatives in a same paragraph or in different paragraphs, a Markush group including a listing of the two or more elements may also be impliedly disclosed. Whenever the auxiliary verb “may” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “may” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method of forming a semiconductor device, comprising:
forming a gate electrode, a source electrode, and a drain electrode within a first dielectric material layer;
depositing a gate dielectric layer over the first dielectric material layer;
forming a source contact via structure and a drain contact via structure through the gate dielectric layer and on the source electrode and the drain electrode, respectively; and
depositing an active layer over the gate dielectric layer.

2. The method of claim 1, further comprising converting end portions of the active layer into a source region and a drain region by implanting electrical dopants into the end portions, wherein an unimplanted portion of the active layer located between the source region and the drain region comprises a channel region.

3. The method of claim 1, further comprising:
forming an ion implantation mask plate including a pair of implantation mask openings over the end portions of the active layer; and
performing an ion implantation process that implants said electrical dopants into the end portions of the active layer using the ion implantation mask plate as an implantation mask, whereby the end portions of the active layer are converted into a source region and a drain region.

4. The method of claim 3, wherein:
the ion implantation mask plate comprises an insulating material; and
the method comprises depositing a second dielectric material layer over the ion implantation mask plate.

5. The method of claim 4, wherein the second dielectric material layer is deposited on each sidewall of the ion implantation mask plate, on a top surface of the ion implantation mask plate, on a top surface segment of the source region, and on a top surface segment of the drain region.

6. The method of claim 3, further comprising:
depositing a semiconducting metal oxide material layer over the gate dielectric layer;
depositing a ion implantation mask material layer over the semiconducting metal oxide material layer; and
patterning the ion implantation mask material layer and the semiconducting metal oxide material layer using a patterned etch mask, wherein a patterned portion of the semiconducting metal oxide material layer comprises the active layer.

7. The method of claim 6, wherein:
a patterned portion of the ion implantation mask material layer comprises an ion implantation mask layer having a same area as the active layer in a plan view; and
the method comprises forming a pair of implantation mask openings through the ion implantation mask layer, whereby the ion implantation mask plate is formed.

8. The method of claim 7, wherein:
the active layer has a rectangular shape with an active layer length along a first horizontal direction and an active layer width along a second horizontal direction; and
each of the pair of implantation mask openings has a respective pair of sidewalls that are parallel to the second horizontal direction and adjoined to two segments of lengthwise sidewalls of the active layer.

9. The method of claim 1, further comprising:
forming a hard mask layer over the gate dielectric layer;
forming a source-side opening and a drain-side opening through the hard mask layer and the gate dielectric layer such that the source-side opening has a first areal overlap with the source electrode and the drain-side opening has a second areal overlap with the drain electrode; and
depositing and recessing at least one metallic material in the source-side opening and the drain-side opening, wherein remaining portions of the at least one metallic material comprise the source contact via structure and the drain contact via structure.

10. The method of claim 9, further comprising:
removing the hard mask layer selectively to the gate dielectric layer, the source contact via structure, and the drain contact via structure;
depositing a semiconducting metal oxide material layer on top surfaces of the gate dielectric layer, the source contact via structure, and the drain contact via structure; and
patterning the semiconducting metal oxide material layer, wherein a patterned portion of the semiconducting metal oxide material layer comprise the active layer.

11. A method of forming a thin film transistor, comprising:
forming a gate electrode, a source electrode, and a drain electrode within a first dielectric material layer;
forming a stack of a gate dielectric layer and a hard mask layer over the first dielectric material layer;
forming a source-side opening and a drain-side opening through the hard mask layer and the gate dielectric layer;
forming a source contact via structure and a drain contact via structure within lower portions of the source-side opening and the drain-side opening through the gate dielectric layer; and
forming an active layer over the gate dielectric layer.

12. The method of claim 11, further comprising removing the hard mask layer selectively to the gate dielectric layer, the source contact via structure, and the drain contact via structure.

13. The method of claim 11, wherein the active layer is formed directly on an entirety of a top surface of the source contact via structure and directly on an entirety of a top surface of the drain contact via structure.

14. The method of claim 11, wherein the source contact via structure and a drain contact via structure are formed by:
depositing at least one metallic material in the source-side opening and the drain-side opening and over the hard mask layer;
removing a first portion of the at least one metallic material from above a horizontal plane including a top surface of the hard mask layer; and
removing second portions of the at least one metallic material from within upper portions of the source-side opening and the drain-side opening through the hard mask layer, wherein remaining portions of the at least one metallic material within lower portions of the source-side opening and the drain-side opening through the gate dielectric layer comprise the source contact via structure and the drain contact via structure.

15. The method of claim 11, further comprising:
depositing a semiconducting metal oxide material layer over the gate dielectric layer after formation of the source contact via structure and the drain contact via structure;
depositing a ion implantation mask material layer over the semiconducting metal oxide material layer;
patterning the ion implantation mask material layer and the semiconducting metal oxide material layer using a patterned etch mask, wherein a patterned portion of the semiconducting metal oxide material layer comprises the active layer, and a patterned portion of the ion implantation mask material layer comprise an ion implantation mask layer;
forming a pair of implantation mask openings through the ion implantation mask layer; and
implanting electrical dopants through the pair of implantation mask openings in the ion implantation mask layer, whereby a source region and a drain region are formed in implanted portions of the active layer.

16. A semiconductor structure comprising:
a gate electrode, a source electrode, and a drain electrode located within a first dielectric material layer;
a gate dielectric layer overlying the first dielectric material layer;
a source contact via structure vertically extending through the gate dielectric layer and contacting the source electrode;
a drain contact via structure vertically extending through the gate dielectric layer and contacting the drain electrode; and
an active layer overlying the gate dielectric layer.

17. The semiconductor structure of claim 16, wherein:
a top surface of the source contact via structure is contacted by the active layer; and
a top surface of the drain contact via structures is contacted by the active layer.

18. The semiconductor structure of claim 16, further comprising an ion implantation mask plate overlying the active layer and comprising a pair of implantation mask openings therethrough, wherein the active layer comprises a source region and a drain region that underlie a respective one of the pair of implantation mask openings.

19. The semiconductor structure of claim 18, further comprising a second dielectric material layer located on sidewalls of the pair of implantation mask openings, a top surface segment of the source region, a top surface segment of the drain region, and a top surface of the ion implantation mask plate.

20. The semiconductor structure of claim 18, wherein:
an outer periphery of a top surface of the active layer aligned to an outer periphery of a bottom surface of the ion implantation mask plate; and
a top surface of the source contact via structure and a top surface of the drain contact via structure are located within a horizontal plane that overlies a first horizontal plane including a bottom surface of the gate dielectric layer and underlies a second horizontal plane including a top surface of the active layer.
